(19) United States
(12) Patent Application Publication
(10) Pub. No.: US 2022/0005931 A1
(43) Pub. Date: Jan. 6, 2022

(54) SEMICONDUCTOR DEVICE AND FORMING METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Nan WANG, Shanghai (CN)

(21) Appl. No.: 17/315,740

(22) Filed: May 10, 2021

(30) Foreign Application Priority Data
Jul. 6, 2020 (CN) 202010641668.X

(51) Int. Cl. H01L 29/423; H01L 29/06; H01L 29/49; H01L 29/786; H01L 21/02; H01L 21/28; H01L 29/66

(52) U.S. Cl. CPC H01L 29/42392; H01L 29/0665; H01L 29/4908; H01L 29/78618; H01L 29/78696; H01L 29/66742; H01L 21/28088; H01L 29/66553; H01L 29/66545; H01L 29/66636; H01L 21/0259

(57) ABSTRACT

A semiconductor device and a forming method thereof are provided. The semiconductor device includes a substrate, a fin located on the substrate, and a gate structure located on the substrate and across the fin. The fin includes a first region, and the fin of the first region includes a gate groove and a channel layer located between adjacent gate grooves. The gate structure covers a sidewall and a top of the fin of the first region, fills the gate groove and surrounds the channel layer. A width of the gate structure located in the gate groove is smaller than a width of the gate structure located on the top of the fin of the first region.

### CROSS-REFERENCE TO RELATED APPLICATION

This application claims priority of Chinese Patent Application No. 202010641668.X, filed on Jul. 6, 2020, the entire content of which is hereby incorporated by reference.

### FIELD OF THE DISCLOSURE

The present disclosure generally relates to the field of semiconductor manufacturing and, more particularly, relates to a semiconductor device and a forming method thereof.

### BACKGROUND

A metal-oxide-semiconductor field effect transistor (MOSFET) is one of the most important components in a modern integrated circuit. A basic structure of a MOSFET includes a semiconductor substrate, and a gate structure located on a surface of the semiconductor substrate. The gate structure includes a gate dielectric layer on the surface of the semiconductor substrate, and a gate electrode layer on a surface of the gate dielectric layer. A basic structure of a MOSFET also includes a source/drain doped region in the semiconductor substrate on two sides of the gate structure.

With development of semiconductor technology, ability of a conventional planar MOSFET for controlling channel current may become weak, resulting in serious leakage current. A fin field effect transistor (Fin FET) is an emerging multi-gate device. A FinFET generally includes a fin protruding from a surface of a semiconductor substrate, a gate structure covering a portion of a top surface and a sidewall of the fin, and a source/drain doped region in the fin on two sides of the gate structure. Compared with a planar MOSFET, a FinFET may have stronger short-channel suppression ability and higher operating current.

With further development of semiconductor technology, a conventional FinFET may have a limitation in further increasing the operating current. Specifically, since only a region close to the top surface and the sidewall of the fin may be used as a channel region, a volume of a portion of the fin used as the channel region may be small. Thus, increase in the operating current of the FinFET may be limited. Accordingly, a gate-all-around (GAA) MOSFET is proposed, such that a volume used as a channel region may be increased, and further operating current of the GAA MOSFET may be increased.

However, in existing technologies, electrical performance of a GAA MOSFET may still need to be improved. The disclosed structures and methods are directed to solve one or more problems set forth above and other problems in the art.

### BRIEF SUMMARY OF THE DISCLOSURE

One aspect of the present disclosure includes a semiconductor device. The device includes a substrate, a fin located on the substrate, and a gate structure located on the substrate and across the fin. The fin includes a first region, and the fin of the first region includes a gate groove and a channel layer located between adjacent gate grooves. The gate structure covers a sidewall and a top of the fin of the first region, fills the gate groove and surrounds the channel layer. A width of the gate structure located in the gate groove is smaller than a width of the gate structure located on the top of the fin of the first region.

Optionally, the device also includes a sidewall spacer. The sidewall spacer is located on a sidewall of the gate structure, and the sidewall spacer includes a stacked structure including a first sidewall spacer and a second sidewall spacer. The first sidewall spacer is located on a sidewall of the gate structure, and the second sidewall spacer is located on a sidewall of the first sidewall spacer.

Optionally, the device also includes a barrier layer. The barrier layer is located on a sidewall of the gate structure in the gate groove.

Optionally, a sidewall of the barrier layer is located between the sidewall of the first sidewall spacer and a sidewall of the second sidewall spacer, or the sidewall of the barrier layer is located between the sidewall of the gate structure and the sidewall of the first sidewall spacer, or the sidewall of the barrier layer is flush with the sidewall of the second sidewall spacer.

Optionally, the fin also includes a second region and a source/drain doped layer located in the fin of the second region. The fin of the second region is located on two sides of the gate structure.

Optionally, the channel layer is made of monocrystalline silicon.

Optionally, the gate structure includes a gate dielectric layer formed on a surface of the channel layer and a sidewall of the first sidewall spacer, a work function layer on the gate dielectric layer, and a gate electrode layer on the work function layer.

Optionally, the gate dielectric layer is made of a high-k dielectric material with a dielectric coefficient k greater than approximately 3.9. The high-k dielectric material includes at least one or a combination of hafnium oxide, zirconium oxide, hafnium silicon oxide, lanthanum oxide, zirconium silicon oxide, titanium oxide, tantalum oxide, barium strontium titanium oxide, barium titanium oxide, strontium titanium oxide, or aluminum oxide.

Optionally, the work function layer is made of a material including at least one or a combination of titanium nitride, aluminum titanium, or tantalum nitride.

Optionally, the dielectric layer is located on top of the source/drain doped layer and covers the sidewall of the gate structure.

Another aspect of the present disclosure includes a forming method of a semiconductor device. The method includes providing a substrate, and forming a fin on the substrate. The fin includes a plurality of sacrificial layers stacking along a normal direction of a surface of the substrate, and a channel layer located between two adjacent sacrificial layers. The method also includes forming a dummy gate structure on the substrate and across the fin, and etching the fin on two sides of the dummy gate structure, thus forming a source/drain groove in the fin. The method also includes etching a portion of the sacrificial layer on a sidewall of the source/drain groove, thus forming a modified sacrificial layer. A width of the modified sacrificial layer is smaller than a width of the dummy gate structure at a top of the fin.

Optionally, before etching the fin on the two sides of the dummy gate structure, thus forming the source/drain groove in the fin, the method also includes forming a sidewall spacer on a sidewall of the dummy gate structure. The sidewall spacer includes a stacked structure, including a first sidewall spacer and a second sidewall spacer. The first sidewall spacer is located on the sidewall of the dummy gate structure. The second sidewall spacer is located on a sidewall of the first sidewall spacer.

Optionally, in a process of etching the portion of the sacrificial layer on the sidewall of the source/drain groove, thus forming the modified sacrificial layer, a sacrificial-layer groove is formed on two sides of the modified sacrificial layer, and a barrier layer is formed in the sacrificial-layer groove.

Optionally, a sidewall of the barrier layer is located between the sidewall of the first sidewall spacer and a sidewall of the second sidewall spacer, or the sidewall of the barrier layer is located between the sidewall of the gate structure and the sidewall of the first sidewall spacer, or the sidewall of the barrier layer is flush with the sidewall of the second sidewall spacer.

Optionally, after forming the barrier layer, the method also includes forming a source/drain doped layer in the source/drain groove, and forming a dielectric layer on the substrate source/drain doped layer. The dielectric layer covers the sidewall of the dummy gate structure. The method also includes removing the dummy gate structure, thus forming a gate opening in the dielectric layer, and removing the modified sacrificial layer, thus forming a gate groove between adjacent channel layers, between the channel layer and the substrate, and on a top of the channel layer. The method also includes forming a gate structure in the gate opening and the gate groove. The gate structure surrounds the channel layer.

Optionally, forming the fin on the substrate includes forming a fin material film on the substrate. The fin material film includes a plurality of fin sacrificial material films stacking along the normal direction of the surface of the substrate, and an initial channel material film located between two adjacent fin sacrificial material films. Forming the fin on the substrate also includes forming a patterned layer on the fin material film, and using the patterned layer as a mask to etch the fin material film until the surface of the substrate is exposed, thus forming the fin.

Optionally, after forming the fin on the substrate and before forming the dummy gate structure on the substrate and across the fin, the method also includes etching a portion thickness of the substrate using the fin as a mask, and forming an isolation structure on the substrate. A top surface of the isolation structure is flush with or lower than a top surface of the substrate.

Optionally, the dummy gate structure includes a dummy gate dielectric layer on the fin, a dummy gate layer on the dummy gate dielectric layer, and a protection layer on the dummy gate layer.

Optionally, forming the sidewall spacer on the sidewall of the dummy gate structure includes forming a sidewall spacer material layer on a top surface of the dummy gate dielectric layer, a sidewall of the dummy gate layer, and a sidewall and a top surface of the protection layer, and etching back the sidewall spacer material layer until the top surface of the protection layer and the top surface of the dummy gate dielectric layer are exposed, thus forming the sidewall spacer.

Optionally, a process of forming the barrier layer includes, on a sidewall and a bottom surface of the source/drain groove, on a sidewall of the modified sacrificial layer, and on a sidewall and a top surface of the dummy gate structure, forming a first initial barrier layer, etching back the first initial barrier layer until the bottom surface of the source/drain groove and the top surface of the dummy gate structure are exposed, thus forming a second initial barrier layer, etching back the second initial barrier layer until the sidewall of the channel layer is exposed, thus forming a third initial barrier layer, and etching back the third initial barrier layer until a portion of the sacrificial-layer groove is exposed, thus forming the barrier layer.

As disclosed, the technical solutions of the present disclosure have the following advantages.

In the semiconductor device provided by the present disclosure, the gate structure is located on the substrate and across the fin, and covers a sidewall and a top of the fin of the first region. The gate structure fills the gate groove and surrounds the channel layer. A width of the gate structure located in the gate groove is smaller than a width of the gate structure located at the top of the fin of the first region. On one hand, since the width of the gate structure located in the gate groove is small, that is, a width of the gate structure controlling the channel is small, a corresponding feature size may be small. Accordingly, the semiconductor device may have a higher the integration level, better performance, and lower the power consumption. On an other hand, the width of the gate structure at the top of the fin in the first region is large. Accordingly, filling difficulty of the gate structure in a formation process may decrease, such that quality of the gate structure finally formed may be improved.

In the forming method of a semiconductor device provided by the present disclosure, after forming the dummy gate structure, the fin on two sides of the dummy gate structure is etched to form a source/drain groove in the fin. A portion of the sacrificial layer on a sidewall of the source/drain groove is etched to form a modified sacrificial layer. A width of the modified sacrificial layer is smaller than a width of the dummy gate structure. In a subsequent process of forming a gate structure, the modified sacrificial layer reserves space for the gate structure to be formed between the channel layers. After removing the modified sacrificial layer, a portion of the gate structure may be formed surrounding the channel layer. After removing the dummy gate structure, a portion of the gate structure may be formed on the top surface of the fin. Since the width of the modified sacrificial layer is smaller than the width of the dummy gate structure, a width of the portion of the gate structure formed on the top surface of the fin is larger than a width of the portion of the gate structure formed between the channel layers. On one hand, the dummy gate structure on the top of the fin may form a larger gate opening during a removal process, and the gate opening may be easily filled with the gate structure in the subsequent manufacturing process. Accordingly, holes may not be formed in the gate structure, difficulty of forming the gate structure may be reduced, and quality of the formed gate structure may be improved. On an other hand, the width of the gate structure between the channel layers may be small. The small width of the gate between the channel layers may correspond to a small feature size of the semiconductor device. In this way, the semiconductor device may have a higher integration level, better performance, and lower power consumption.

### BRIEF DESCRIPTION OF THE DRAWINGS

The following drawings are merely examples for illustrative purposes according to various disclosed embodiments and are not intended to limit the scope of the present disclosure.

FIG. 1 to FIG. 3 illustrate a structural diagram of a semiconductor device;

FIGS. 4 to 17 illustrate semiconductor structures corresponding to certain stages of an exemplary forming method of a semiconductor device, consistent with the disclosed embodiments of the present disclosure;

FIG. 18 illustrates a semiconductor structure corresponding to a stage of another exemplary forming method of a semiconductor device, consistent with the disclosed embodiments of the present disclosure;

FIG. 19 illustrates a flowchart of an exemplary forming method of a semiconductor device, consistent with the disclosed embodiments of the present disclosure; and

FIG. 20 illustrates a flowchart of another exemplary forming method of a semiconductor device, consistent with the disclosed embodiments of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Reference will now be made in detail to exemplary embodiments of the present disclosure, which are illustrated in the accompanying drawings. Wherever possible, the same reference numbers will be used throughout the drawings to refer to the same or like parts.

A gate structure is an important component in a semiconductor device. Quality of the gate structure may directly affect quality of the semiconductor device subsequently formed. FIG. 1 to FIG. 3 illustrate a structural diagram of a semiconductor device. With reference to FIG. 1 to FIG. 3, a forming process of a gate structure in existing technology is described below.

As shown in FIG. 1, the forming process includes providing a substrate 100, a fin 101 on the substrate 100, and a dummy gate structure on the substrate 100 and across the fin 101. The dummy gate structure includes a dummy gate dielectric layer 102 on a surface of the fin 101, a dummy gate electrode layer 103 on the dummy gate dielectric layer 102, and a sidewall spacer 104 on the dummy gate dielectric layer 102. The forming process also includes providing a source/drain doped layer 105 in the fin 101 on two sides of the sidewall spacer 104, and a dielectric layer 106 on the substrate 100. The dielectric layer 106 is located on a sidewall of the sidewall spacer 104 and exposes a top surface of the dummy gate electrode layer 103.

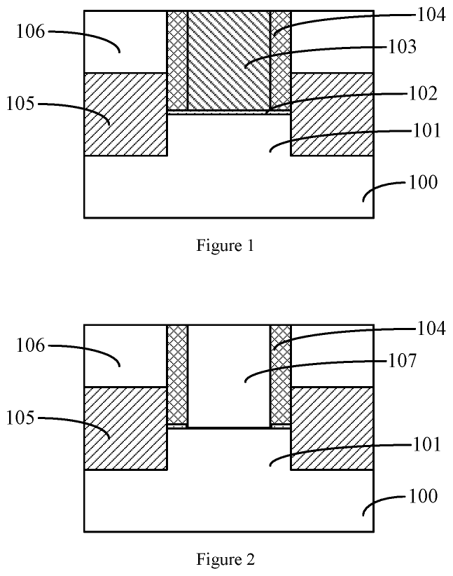

As shown in FIG. 2, the forming process also includes removing the dummy gate electrode layer 103 and the dummy gate dielectric layer 102 at a bottom of the dummy gate electrode layer 103, forming a gate opening 107.

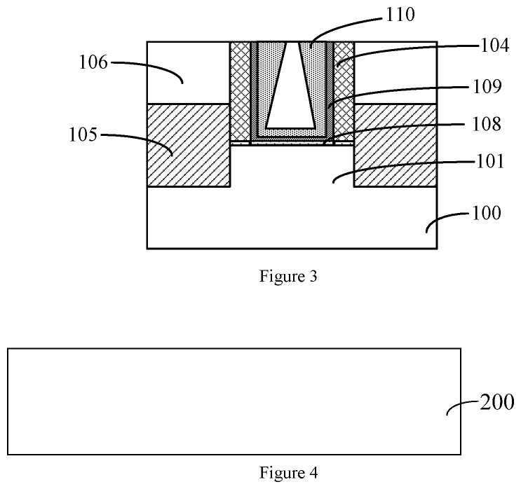

As shown in FIG. 3, the forming process also includes forming a gate structure in the gate opening 107. Forming the gate structure includes forming a gate dielectric layer 108 on a bottom and a sidewall of the gate opening 107, forming a work function layer 109 on the gate dielectric layer 108, and forming a gate electrode layer 110 on the work function layer 108.

The inventor finds that the gate structure formed by the forming process described above may have a hole defect (as shown in FIG. 3). Thus, quality of the gate structure formed may be poor, and performance of the semiconductor device formed may be affected. A reason for the hole defect includes that, as a feature size of a semiconductor device is getting smaller and smaller, a feature size of a gate structure needs to be formed is also getting smaller and smaller. On one hand, in a process of removing a dummy gate structure, a portion of the dummy gate structure may remain. In a process of forming the gate structure, since a gate opening may be small, internal air pressure may have a strong hindering effect on the gate structure, and thus forming the gate structure may be difficult. On an other hand, as the feature size of the gate structure becomes smaller and smaller, during a forming process of the gate structure, a hole may be formed in the gate structure. As a result, quality of the gate structure finally formed may be poor, and electrical performance of the semiconductor device finally formed may be affected.

The inventor finds through research that a gate-all-around (GAA) structure may be formed, such that a width of a gate structure located in a gate groove is smaller than the width of the gate structure located on top of a fin. In a forming process of such a gate structure with a wide top and a narrow bottom, on one hand, a high-quality gate structure may be formed, and on an other hand, a gate structure with a small feature size may be formed. Accordingly, quality of the gate structure formed may be improved, and an integration level of a semiconductor device finally formed may be improved.

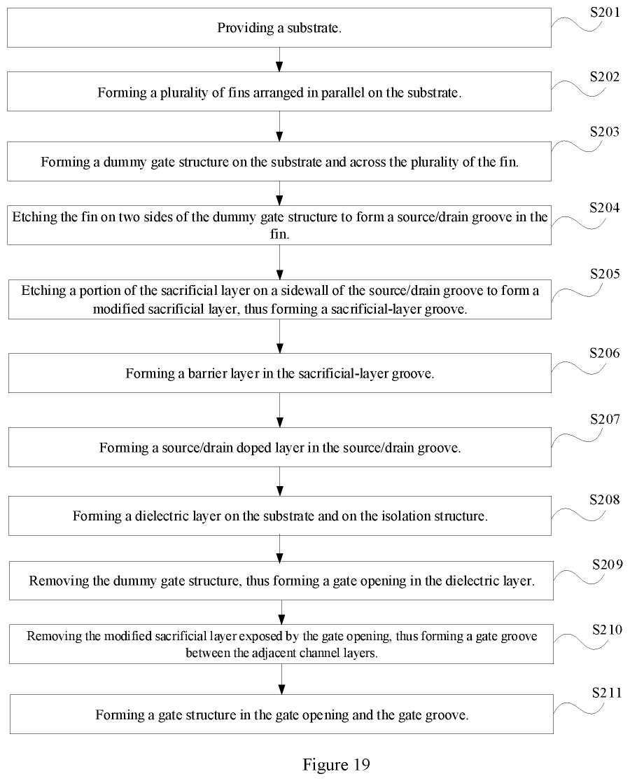

FIG. 19 illustrates a flowchart of an exemplary forming method of a semiconductor device, consistent with the disclosed embodiments of the present disclosure. FIGS. 4 to 17 illustrate semiconductor structures corresponding to certain stages of the exemplary forming method of the semiconductor device, consistent with the disclosed embodiments of the present disclosure.

As shown in FIG. 19, at the beginning of the forming method, a substrate is provided (S201). FIG. 4 illustrates a corresponding semiconductor structure.

As shown in FIG. 4, a substrate 200 is provided. In one embodiment, the substrate 200 is made of a material including monocrystalline silicon.

In some other embodiments, the substrate 200 may be made of a material including polysilicon or amorphous silicon. In some other embodiments, the substrate 200 may be made of a semiconductor material, such as germanium, silicon germanium, gallium arsenide, silicon-on-insulator (SOI), germanium-on-insulator (GOI), etc., or a multi-semiconductor material composed of group III-V elements, including InP, GaAs, GaP, InAs, InSb, InGaAs, or InGaAsP, etc.

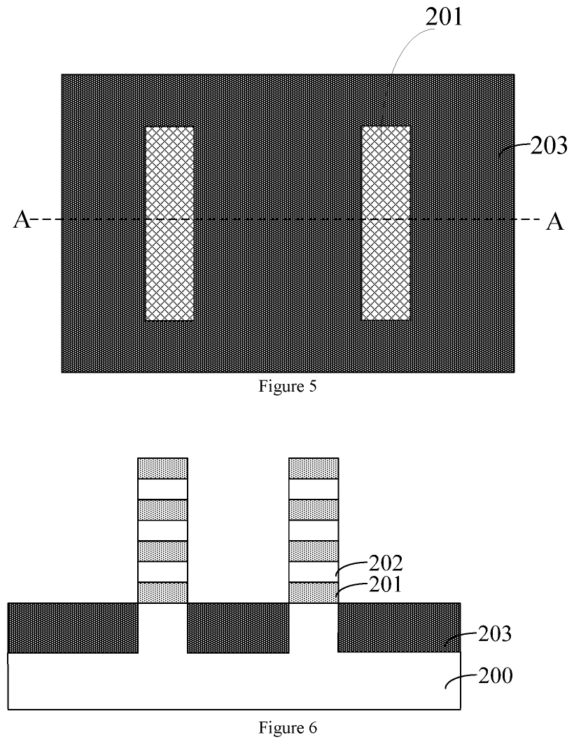

Returning to FIG. 19, after providing the substrate 200, a plurality of fins arranged in parallel may be formed on the substrate (S202). FIGS. 5 and 6 illustrate a corresponding semiconductor structure. FIG. 5 is a top view of FIG. 6, and FIG. 6 is a schematic cross-sectional view taken along line A-A in FIG. 5.

As shown in FIG. 5 and FIG. 6, a plurality of fins arranged in parallel is formed on the substrate 200. A fin of the plurality of fins includes a plurality of sacrificial layers 201 stacking along a normal direction of a surface of the substrate 200, and a channel layer 202 located between two adjacent sacrificial layers 201.

The semiconductor structure shown in FIG. 5 and FIG. 6 includes two fins, four sacrificial layers 201, and three channel layers 202.

In one embodiment, a process of forming the fin includes forming a fin material film (not shown) on the substrate 200. The fin material film includes a plurality of fin sacrificial material films stacking along the normal direction of the surface of the substrate 200, and an initial channel material film located between two adjacent fin sacrificial material films. The process also includes forming a patterned layer (not shown) on the fin material films, and using the patterned layer as a mask to etch the fin material films until the surface of the substrate 200 is exposed, thus forming the fin. The fin includes a plurality of sacrificial layers 201 stacking along the normal direction of the surface of the substrate 200, and a channel layer 202 located between two adjacent sacrificial layers 201.

In one embodiment, the sacrificial layer 201 and the channel layer 202 are made of different materials. When subsequently forming a gate structure, the sacrificial layer 201 needs to be removed. Accordingly, by using the sacrificial layer 201 and the channel layer 202 made of different materials to achieve a large etching selection ratio, damage to the channel layer 202 in a process of removing the sacrificial layer 201 may be reduced.

In one embodiment, the sacrificial layer 201 is made of silicon germanium, and the channel layer 202 is made of monocrystalline silicon.

In one embodiment, after etching the fin material film to form the fin, the process also includes etching a portion thickness of the substrate 200 using the fin as a mask, and forming an isolation structure 203 on the substrate 200. A top surface of the isolation structure 203 is not higher than (that is, flush with or lower than) a top surface of the substrate 200.

In one embodiment, the isolation structure 203 is made of a material including silicon nitride. In some other embodiments, the isolation structure 203 may be made of one or a combination of insulating materials including silicon oxide, silicon oxynitride (SiON), silicon carbide (SiC), silicon oxycarbide (SiOC), silicon carbonitride (SiCN), silicon carbon oxynitride (SiOCN) and silicon carbon nitride boride (SiCBN).

In one embodiment, a function of the isolation structure 203 includes forming electrical isolation.

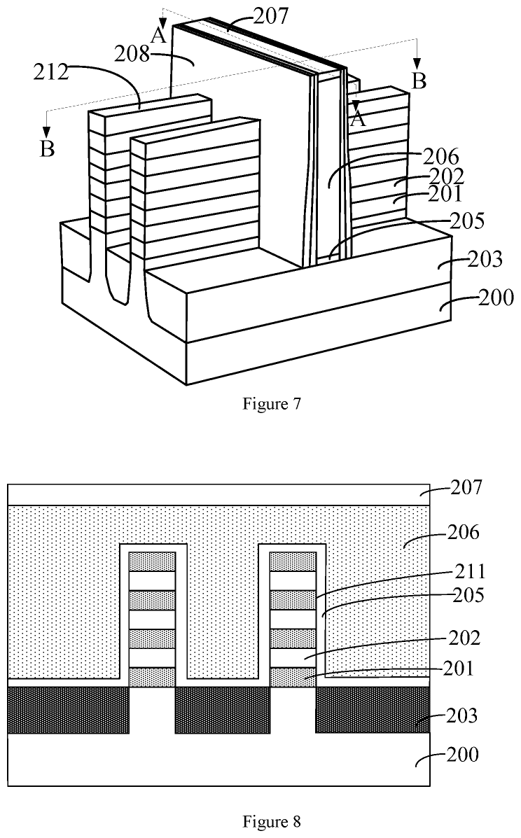

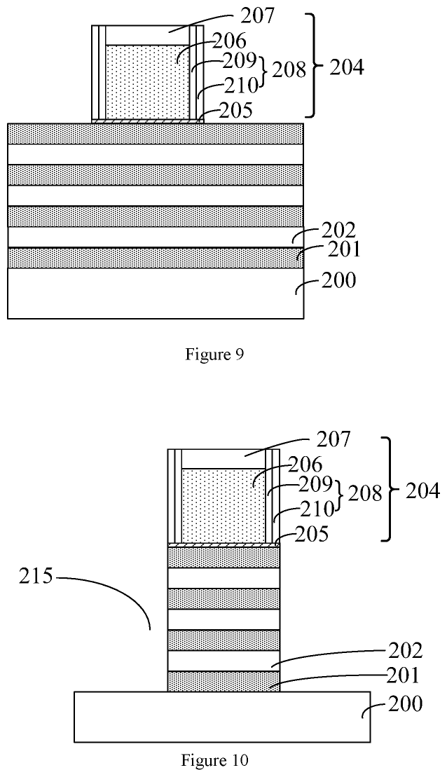

Returning to FIG. 19, after forming the plurality of fins arranged in parallel on the substrate, a dummy gate structure may be formed on the substrate and across the plurality of the fin (S203). FIGS. 7-9 illustrate a corresponding semiconductor structure. FIG. 7 is a perspective view of FIGS. 8 and 9. FIG. 8 is a cross-sectional view of FIG. 7 in section A-A, and FIG. 9 is a cross-sectional view of FIG. 7 in section B-B.

As shown in FIGS. 7-9, a dummy gate structure 204 is formed on the substrate 200 across the plurality of fins. In one embodiment, the dummy gate structure 204 includes a dummy gate dielectric layer 205 on the fins, a dummy gate layer 206 on the dummy gate dielectric layer 205, a protection layer 207 on the dummy gate layer 206, and a sidewall spacer 208 on sidewalls of the dummy gate layer 206 and the protection layer 207.

In one embodiment, the dummy gate layer 206 is made of a material including silicon.

In one embodiment, the protection layer 207 is made of a material including silicon nitride. In some other embodiments, the protection layer 207 may be made of one or a combination of insulating materials including silicon oxide, silicon oxynitride (SiON), silicon carbide (SiC), silicon oxycarbide (SiOC), silicon carbonitride (SiCN), silicon carbon oxynitride (SiOCN) and silicon carbon nitride boride (SiCBN).

In one embodiment, the sidewall spacer 208 includes a stacked structure. The sidewall spacer 208 includes a first sidewall spacer 209 and a second sidewall spacer 210. The first sidewall spacer 209 is located on a sidewall of the dummy gate structure 204, and the second sidewall spacer 210 is located on a sidewall of the first sidewall spacer 209. In some other embodiments, the sidewall spacer 208 may include a single-layer structure, a three-layer structure or even a stacked structure with more layers.

In one embodiment, for the sidewall spacer 208 with the stacked structure, the second sidewall spacer 210 may protect the first sidewall spacer 209 from damage during a subsequent etching process. Accordingly, a width of the gate structure between the first sidewall spacers 209 may be guaranteed.

A forming process of the sidewall spacer 208 includes forming a sidewall spacer material layer (not shown) on a top surface of the dummy gate dielectric layer 205, a sidewall of the dummy gate layer 206, and a sidewall and a top surface of the protection layer 207. The forming process also includes etching back the sidewall spacer material layer until the top surfaces of the protection layer 207 and the dummy gate dielectric layer 205 are exposed, thus forming the sidewall spacer 208.

A forming process of the sidewall spacer material layer may include one or a combination of chemical vapor deposition (CVD), physical vapor deposition (PVD), atomic layer deposition (ALD), or heat treatment. In one embodiment, the forming process of the sidewall material layer includes the atomic layer deposition process.

In one embodiment, the first sidewall spacer 209 is made of silicon nitride, and the second sidewall spacer 210 is made of silicon oxide.

In some other embodiments, the first sidewall spacer 209 may be made of at least one of materials including silicon oxide, silicon oxynitride, silicon oxycarbide, silicon carbonitride, silicon oxycarbonitride, and silicon carbonitride boride. The second sidewall spacer 210 may be made of at least one of materials including silicon oxide, silicon oxynitride, silicon oxycarbide, silicon carbonitride, silicon oxycarbonitride, and silicon carbonitride boride.

In one embodiment, the sidewall spacer 208 is used to define a position of a source/drain doped layer subsequently formed.

In one embodiment, the dummy gate structure 204 covers a portion of the sidewall and the top of the fin, such that the fin may be divided into a first region 211 and a second region 212. The top and the sidewall surface of the fin at the first region 211 are covered by the dummy gate structure 204. The fin at the second region 212 is not covered by the dummy gate structure 204.

Returning to FIG. 19, after forming the dummy gate structure on the substrate across the plurality of the fins, the fin on two sides of the dummy gate structure may be etched to form a source/drain groove in the fin (S204). FIG. 10 illustrates a corresponding semiconductor structure. View directions of FIG. 10 and FIG. 9 are same.

As shown in FIG. 10, after the dummy gate structure 204 is formed, the fin on two sides of the dummy gate structure 204 are etched to form a source/drain groove 215 in the fin.

In one embodiment, on one hand, the source/drain groove 215 may provide space for a source/drain doped layer to be formed later. On an other hand, the source/drain groove 215 may make preparation for subsequently etching the sacrificial layer 201 covered by the dummy gate structure 204.

A process of etching the fin to form the source/drain groove 215 includes an anisotropic dry etching process or an anisotropic wet etching process.

In one embodiment, the process of etching the fin includes an anisotropic dry etching process. Parameters of the anisotropic dry etching process are listed below. Etching gas used includes HBr and Ar. A gas flow rate of HBr is in a range of approximately 10 sccm-1000 sccm, and a gas flow rate of Ar is in a range of approximately 10 sccm-1000 sccm.

In one embodiment, the fin is etched to form the source/drain groove 215. A bottom surface of the source/drain groove 215 exposes the top surface of the substrate 200.

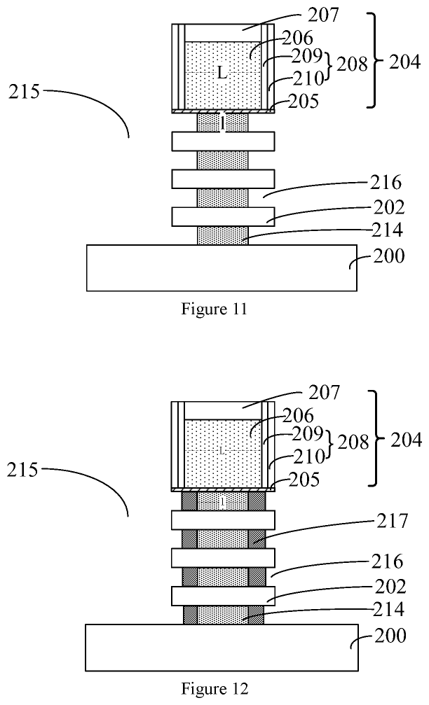

Returning to FIG. 19, after forming the source/drain groove in the fin, a portion of the sacrificial layer on a sidewall of the source/drain groove may be etched to form a modified sacrificial layer, thus forming a sacrificial-layer groove (S205). FIG. 11 illustrates a corresponding semiconductor structure.

As shown in FIG. 11, a portion of the sacrificial layer 201 on the sidewall of the source/drain groove 215 is etched to form a modified sacrificial layer 214. A width of the modified sacrificial layer 214 is smaller than a width of the dummy gate structure 204 at the top of the fin.

In one embodiment, after the sacrificial layer 201 is etched, a sacrificial-layer groove 216 is formed on two sides of the modified sacrificial layer 214. The sacrificial-layer groove 216 provides space for subsequently forming a barrier layer between the source/drain doped layer and the gate structure, such that electrical crosstalk between the source/drain doped layer and the gate structure may be prevented.

In one embodiment, a wet etching process is used to etch a portion of the sacrificial layer 201 on the sidewall of the source/drain groove 215 to form the modified sacrificial layer 214. Since a wet etching process may have a high etching selection ratio, during the etching process of the sacrificial layer 201, the channel layer 202 may not be damaged. Accordingly, the surface of the channel layer 202 may have good quality, and thus quality of the semiconductor device subsequently formed may be improved.

In one embodiment, since a width (1) of the modified sacrificial layer 214 is smaller than a width (L) of the dummy gate structure 204 at the top of the fin, a gate structure with a wide upper and a narrow bottom may be formed subsequently. On one hand, the quality of the gate structure may be improved. On an other hand, the feature size of the gate structure may be reduced. Accordingly, an integration level of the semiconductor device formed may be improved.

In a subsequent process of forming the gate structure, on one hand, the dummy gate structure 204 needs to be removed, and on an other hand, the modified sacrificial layer 214 located between the source/drain grooves 215 needs to be removed. Since the width of the dummy gate structure 204 at the top of the fin is larger than the width of the modified sacrificial layer 214, a larger gate opening may be formed after removing the dummy gate structure 204 at the top of the fin, and after removing the modified sacrificial layer 214, a smaller gate groove may be formed. Due to the larger gate opening, removal of the dummy gate structure 204 and formation of the gate structure may become easier. Further, when forming the gate structure, the larger gate opening may reduce a barrier effect of the gas pressure in the gate opening on the gate structure. Accordingly, formation of hole defects in the gate structure may be avoided and quality of the gate structure formed may be improved. Meanwhile, in an actual working process of an actual semiconductor device, the gate structure in the gate groove controls the channel layer 202. Formation of a gate structure with a smaller width in the gate groove may reduce the feature size of the gate structure. Accordingly, the integration level of the semiconductor device formed may be improved, and an application range of the semiconductor device formed may be extended.

Returning to FIG. 19, after forming the sacrificial-layer groove, a barrier layer may be formed in the sacrificial-layer groove (S206). FIG. 12 illustrates a corresponding semiconductor structure.

As shown in FIG. 12, a barrier layer 217 is formed in the sacrificial-layer groove 216. In one embodiment, the barrier layer 217 is located on the sidewall of the modified sacrificial layer 214 and fills a portion of the sacrificial-layer groove 216.

In one embodiment, a sidewall of the barrier layer 217 is located between the sidewall of the dummy gate structure 204 and the sidewall of the first sidewall spacer 209. Accordingly, the barrier layer 217 may block the punch-through between the gate structure and the source/drain doped layer formed subsequently, and the parasitic capacitance between the gate structure and the source/drain doped layers may be small. Thus, the electrical performance of the semiconductor device formed may be improved.

In some other embodiments, the sidewall of the barrier layer 217 may be located between the sidewall of the first side wall 209 and the sidewall of the second sidewall spacer 210.

In one embodiment, the side wall of the barrier layer 217 is flush with the sidewall of the second sidewall spacer 210.

In one embodiment, the barrier layer 217 is made of a material with a low dielectric constant, including at least one of SiOCN, SiOC, and SiON.

In one embodiment, the barrier layer 217 may play a role in shaping the gate structure to be formed subsequently. Accordingly, the gate structure to be formed subsequently may be wide at the top and narrow at the bottom.

In one embodiment, a process of forming the barrier layer 217 includes, on the sidewall and the bottom surface of the source/drain groove 215, on the sidewall of the modified sacrificial layer 214, and on the sidewall and the top surface of the dummy gate structure, forming a first initial barrier layer (not shown). The process also includes etching back the first initial barrier layer until the bottom surface of the source/drain groove 215 and the top surface of the dummy gate structure are exposed, and thus forming a second initial barrier layer. The process also includes etching back the second initial barrier layer until the sidewall of the channel layer 202 is exposed, thus forming a third initial barrier layer. The process also includes etching back the third initial barrier layer until a portion of the sacrificial-layer groove 216 is exposed, thus forming the barrier layer 217.

In one embodiment, the barrier layer 217 is made of a material including silicon nitride.

A process of forming the first initial barrier layer includes one of processes including physical vapor deposition (PVD), chemical vapor deposition (CVD), atomic layer deposition (ALD), heat treatment, etc. In one embodiment, the process of forming the first initial barrier layer includes the atomic layer deposition process.

A process of etching back the first initial barrier layer, the second initial barrier layer, and the third initial barrier layer includes a wet etching process or a dry etching process. In one embodiment, the process of etching back the first initial barrier layer, the second initial barrier layer, and the third initial barrier layer includes a dry etching process. Parameters of the dry etching process are listed below. Etching gas includes CF₄ and CH₂F₂. A flow rate of CF₄ is in a range of approximately 50 sccm to 500 sccm, and a flow rate of CH₂F₂ is in a range of approximately 30 sccm to 100 sccm.

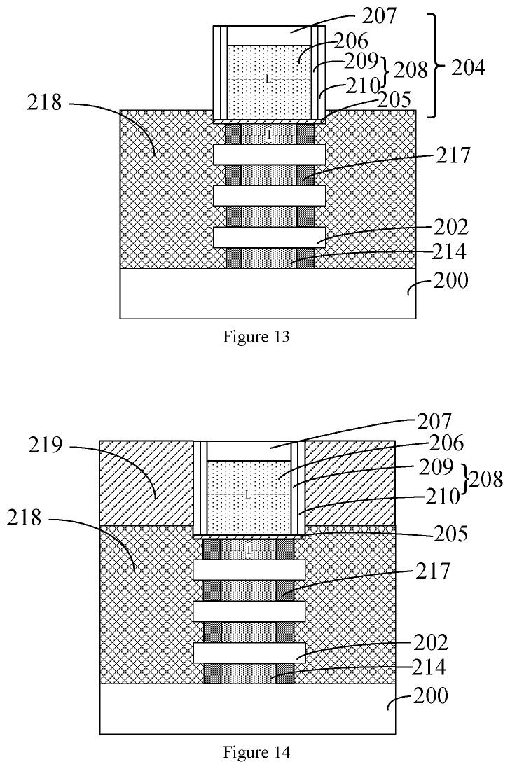

Returning to FIG. 19, after forming the barrier layer in the sacrificial-layer groove, a source/drain doped layer may be formed in the source/drain groove (S207). FIG. 13 illustrates a corresponding semiconductor structure.

As shown in FIG. 13, after forming the barrier layer 217, a source/drain doped layer 218 may be formed in the source/drain grooves 215 and a portion of the sacrificial-layer groove 216.

In one embodiment, a process of forming the source/drain doped layer 218 includes an epitaxial growth process. A process of doping the source/drain ions in the source/drain doped layer 218 includes an in-situ doping process.

When the semiconductor structure is a P-type device, the source/drain doped layer 215 is made of a material including silicon, germanium, or silicon germanium. The source/drain ions are P-type ions. The source/drain ions may include boron ions, BF²⁻ ions, or indium ions. When the semiconductor structure is an N-type device, the source/drain doped layer 215 is made of a material including silicon, gallium arsenide or indium gallium arsenide. The source/drain ions are N-type ions. The source/drain ions may include phosphorus ions or arsenic ions.

Returning to FIG. 19, after forming the source/drain doped layer, a dielectric layer may be formed on the substrate and on the isolation structure (S208). FIG. 14 illustrates a corresponding semiconductor structure.

As shown in FIG. 14, after forming the source/drain doped layer 218, a dielectric layer 219 is formed on the substrate 200 and on the isolation structure 203. The dielectric layer 219 is located on the sidewall of the sidewall spacer 208 and exposes the top surface of the protection layer 207.

In one embodiment, the dielectric layer 219 is specifically formed on the isolation structure 203, and the dielectric layer 219 also covers the source/drain doped layers 218.

In one embodiment, a process of forming the dielectric layer 219 includes forming an initial dielectric layer (not shown) on the substrate 200 and on the isolation structure 203. The initial dielectric layer covers the top surface and sidewall surfaces of the protection layer 207. The process also includes planarizing the initial dielectric layer until the top surface of the protection layer 207 is exposed, thus forming the dielectric layer 219. In one embodiment, the dielectric layer 219 is made of a material including silicon oxide.

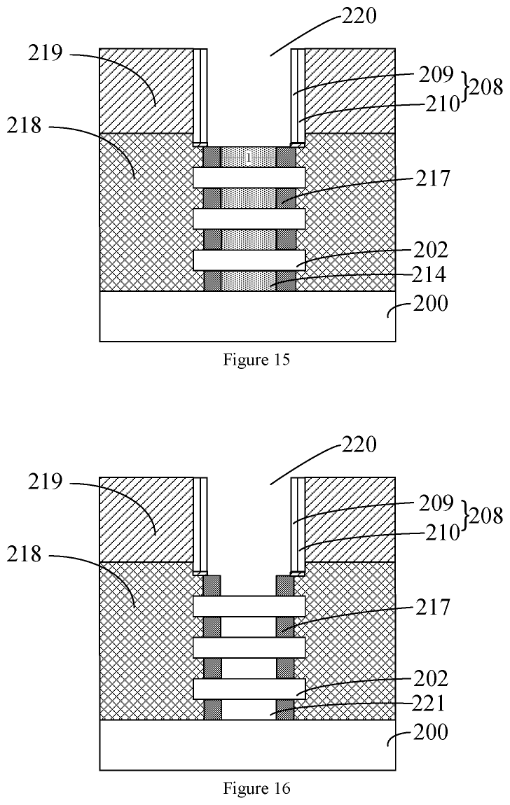

Returning to FIG. 19, after forming the dielectric layer, the dummy gate structure may be removed, thus forming a gate opening in the dielectric layer (S209). FIG. 15 illustrates a corresponding semiconductor structure.

As shown in FIG. 15, the dummy gate structure 204 is removed, and a gate opening 220 is thus formed in the dielectric layer 219. In one embodiment, a process for removing the dummy gate structure 204 is a wet etching process. Specifically, an etching solution includes tetramethylammonium hydroxide (TMAH).

In one embodiment, removing dummy gate structure 204 makes preparation for subsequently forming a gate structure. In one embodiment, the protection layer 207, the dummy gate layer 206 and the dummy gate dielectric layer 205 located at the bottom of the protection layer 207 are removed.

Returning to FIG. 19, after forming the gate opening in the dielectric layer, the modified sacrificial layer exposed by the gate opening may be removed, and a gate groove may thus be formed between the adjacent channel layers (S210). FIG. 16 illustrates a corresponding semiconductor structure.

As shown in FIG. 16, the modified sacrificial layer 214 exposed by the gate opening 220 is removed, and a gate groove 221 is thus formed between the adjacent channel layers 202.

In one embodiment, a width (L) of the gate opening 220 is greater than a width (l) of the gate groove 221. Since the width of the gate opening 220 is large, the dummy gate structure 204 may be removed easily, and thus residue of the dummy gate structure 204 may not appear. In addition, since the width of the gate opening 220 is large, during a subsequent process of filling the gate opening 220 with a gate structure, the gate opening 220 may have little blocking ability to the gate structure. Accordingly, a hole may not be formed in the gate structure, and thus quality of the gate structure formed may be improved.

In addition, since a width of the gate structure formed in the gate groove 221 is small, a width of the gate controlling the channel layer 202 may be reduced, such that the feature size of the gate structure may decrease. Accordingly, a highly integrated semiconductor device may be formed, and thus an application range of the semiconductor device may be extended.

In one embodiment, a process of removing the modified sacrificial layer 214 exposed by the gate opening 220 includes a wet etching process. In some other embodiments, the process of removing the modified sacrificial layer 214 exposed by the gate opening 220 may include a dry etching process.

In one embodiment, a wet etching process is used to remove the modified sacrificial layer 214 exposed by the gate opening 220. Since the wet etching process may have a high etching selection ratio, in a process of removing the modified sacrificial layer 214 exposed by the gate opening 220, the surface of the channel layer 202 may not be damaged or may be hardly damaged. Accordingly, the surface of the channel layer 202 may have good quality, and a high-quality semiconductor device may be formed.

In one embodiment, parameters of the wet etching process include a temperature in a range of approximately 25° C. to 300° C., and a volume percentage of HCl gas in a range of 20% to 90%.

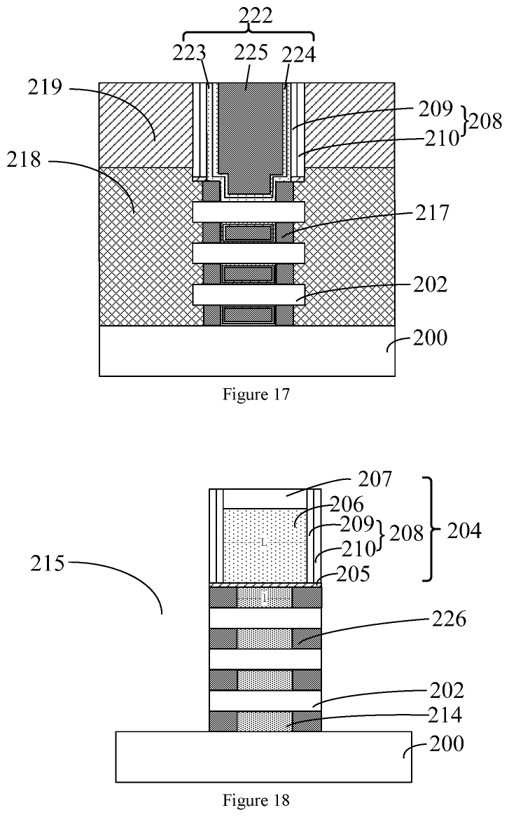

Returning to FIG. 19, after forming the gate groove between the adjacent channel layers, a gate structure may be formed in the gate opening and the gate groove (S211). FIG. 17 illustrates a corresponding semiconductor structure.

As shown in FIG. 17, a gate structure 222 is formed in the gate opening 220 and the gate groove 221. The gate structure 222 surrounds the channel layer 202.

In one embodiment, the gate structure 222 may have a T-shaped structure along a direction perpendicular to the substrate 200. That is, a width of the gate structure located in the gate opening 220 is greater than a width of the gate structure located in the gate groove 221. With such a configuration, during a forming process, the gate structure may be dense inside, resulting in high forming quality. In addition, since the width of the gate structure controlling the channel layer 202 is small, a highly integrated semiconductor device may be formed, and thus the application range of the semiconductor device may be extended.

In one embodiment, the gate structure 222 includes a gate dielectric layer 223 formed on a surface of the channel layer 202 and the sidewall of the first sidewall spacer 209, a work function layer 224 on the gate dielectric layer 223, and a gate electrode layer 225 on the work function layer 224.

In one embodiment, the gate dielectric layer 223 is made of a high-k dielectric material (dielectric coefficient k is greater than approximately 3.9). The high-k dielectric material includes at least one of hafnium oxide, zirconium oxide, hafnium silicon oxide, lanthanum oxide, zirconium silicon oxide, titanium oxide, tantalum oxide, barium strontium titanium oxide, barium titanium oxide, strontium titanium oxide, or aluminum oxide.

In one embodiment, the work function layer 224 is made of at least one of titanium nitride, aluminum titanium, or tantalum nitride.

In one embodiment, the gate electrode layer 225 is made of a metal material. The metal material includes one or a combination of copper, tungsten, nickel, chromium, titanium, tantalum, and aluminum.

The present disclosure also provides a semiconductor device. The semiconductor device includes a substrate 200 and a fin located on the substrate 200. The fin includes a first region 211. The fin of the first region 211 includes a gate groove 221 and a channel layer 202 located between adjacent gate grooves 221. The semiconductor device also includes a gate structure 222, located on the substrate 200 and across the fin. The gate structure 222 covers a sidewall and a top of the fin of the first region 211, filling the gate groove 221 and surrounding the channel layer 202. A width of the gate structure 222 located in the gate groove 221 is smaller than a width of the gate structure 222 located at the top of the fin of the first region 211.

In one embodiment, the gate structure 222 has a T-shaped structure. That is, the width of the gate structure located in the gate opening 220 is greater than the width of the gate structure located in the gate groove 221. With such a configuration, during a forming process, the gate structure may be dense inside, resulting in high forming quality. In addition, since the width of the gate structure controlling the channel layer 202 is small, a highly integrated semiconductor device may be formed, and thus the application range of the semiconductor device may be extended.

The semiconductor device also includes a sidewall spacer 208. The sidewall spacer 208 is located on a sidewall of the gate structure 222, and the sidewall spacer 208 may have a stacked structure.

In one embodiment, the sidewall spacer 208 has a stacked structure. The sidewall spacer 208 includes a first sidewall spacer 209 and a second sidewall spacer 210. The first sidewall spacer 209 is located on a sidewall of the dummy gate structure 204, and the second sidewall spacer 210 is located on a sidewall of the first sidewall spacer 209.

In one embodiment, for the sidewall spacer 208 with the stacked structure, the second sidewall spacer 210 may protect the first sidewall spacer 209 from damage during a subsequent etching process. Accordingly, a width of the gate structure between the first sidewall spacers 209 may be guaranteed.

The semiconductor device also includes a barrier layer 217. The barrier layer 217 is located on the sidewall of the gate structure 222 in the gate groove 221.

In one embodiment, the sidewall of the barrier layer 217 is located between the sidewall of the gate structure 222 and the sidewall of the first sidewall spacer 209. In some other embodiments, the sidewall of the barrier layer 217 may be located between the sidewall of the first sidewall spacer 209 and the sidewall of the second sidewall spacer 210, or the sidewall of the barrier layer 217 is flush with the sidewall of the second sidewall spacer 210.

In one embodiment, the sidewall of the barrier layer 217 is located between the sidewall of the dummy gate structure 204 and the sidewall of the first sidewall spacer 209. Accordingly, the barrier layer 217 may block the punch-through between the gate structure formed subsequently and the source/drain doped layer, and the parasitic capacitance between the gate structure and the source/drain doped layer may be small. Thus, the electrical performance of the semiconductor device formed may be improved.

In one embodiment, due to the barrier layer 217, a T-shaped gate structure with a wide top and a narrow bottom may be formed subsequently. That is, the width of the gate structure in the gate opening is greater than the width of the gate structure in the gate groove. The sidewall of the barrier layer 217 is away from the sidewall of the sidewall spacer 208, and a distance between the barrier layers 217 is small. In this way, when forming a long transistor with a small-sized gate structure, a distance between the sidewall spacers 208 is greater than the distance between the barrier layers 217. The gate opening formed after removing the dummy gate structure 204 inside the sidewall spacer 208 is large. The gate groove formed after removing the modified sacrificial layer 214 between the barrier layers 217 has a small opening. Due to the large gate opening, in a process of forming the gate structure, a work function layer and a gate electrode layer with good quality and high uniformity may be formed.

In one embodiment, the barrier layer 217 also has a function of isolating the source/drain doped layer and the gate structure formed subsequently, to prevent the punch-through between the source/drain doped layer and the gate structure.

The fin also includes a second region 212. The fin of the second region 212 includes a sacrificial layer 201 and a channel layer 202 located between two adjacent sacrificial layers 201. The fin of the second region 212 are located on two sides of the gate structure 222. The fin of the second region 212 is adjacent to the fin of the first region 211.

The fin also includes a source/drain doped layer 218. The source/drain doped layer 218 is located in the fin of the second region 212 on two sides of the gate structure 222.

When the semiconductor structure is a P-type device, the source/drain doped layer 215 is made of a material including silicon, germanium, or silicon germanium. The source/drain ions are P-type ions. The source/drain ions may include boron ions, BF²⁻ ions, or indium ions. When the semiconductor structure is an N-type device, the source/drain doped layer 215 is made of a material including silicon, gallium arsenide or indium gallium arsenide. The source/drain ions are N-type ions. The source/drain ions may include phosphorus ions or arsenic ions.

The semiconductor device also includes a dielectric layer 219. The dielectric layer 219 is located on top of the source/drain doped layer 218 and covers the sidewall of the gate structure 222. In one embodiment, the dielectric layer 219 is made of silicon oxide.

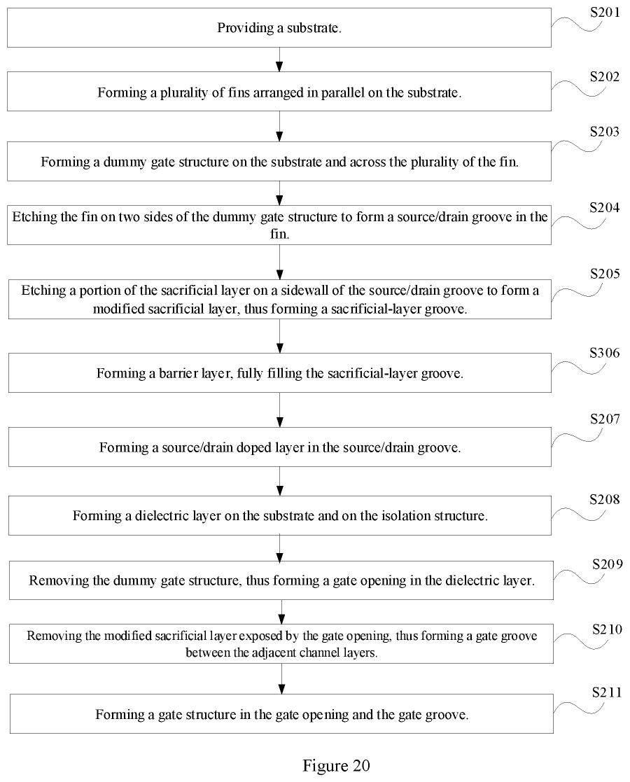

FIG. 20 illustrates a flowchart of another exemplary forming method of a semiconductor device, consistent with the disclosed embodiments of the present disclosure. With reference to FIG. 19 and FIG. 20, for steps S201-S205 and steps S207-S211, the exemplary forming method illustrated in FIG. 19 and the another exemplary forming method illustrated in FIG. 20 are same.

As shown in FIG. 20, for a process from providing a substrate 200 to forming the sacrificial-layer groove 216 (steps S201-S205), reference may be made to FIGS. 4 to 11.

Returning to FIG. 20, after forming the modified sacrificial layer, a barrier layer may be formed, fully filling the sacrificial-layer groove 216 (S306). FIG. 18 illustrates a corresponding semiconductor structure.

As shown in FIG. 18, the barrier layer 226 is formed in the sacrificial-layer groove 216. The barrier layer 226 fully fills the sacrificial-layer groove 216, and a sidewall of the barrier layer is flush with the sidewall of the second sidewall spacer 210.

In one embodiment, the barrier layer 226 is made of a low-k (dielectric constant) material, including at least one of SiOCN, SiOC, and SiON.

In one embodiment, a process for forming the barrier layer 226 includes forming a first initial barrier layer (not shown) on the sidewall and bottom surface of the source/drain groove 215, and the sidewall and top surface of the dummy gate structure. The process also includes etching back the first initial barrier layer until the bottom surface of the source/drain groove 215 and the top surface of the dummy gate structure are exposed, thus forming a second initial barrier layer. The method also includes etching the second initial barrier layer until the sidewall of the channel layer 202 is exposed, thus forming the barrier layer 226.

Returning to FIG. 20, after forming the barrier layer, for steps S207-S211, reference may be made to FIGS. 13 to 17.

The present disclosure also provides another semiconductor device. The semiconductor device includes a substrate 200 and a fin located on the substrate 200. The fin includes a first region 211. The fin of the first region 211 includes a gate groove 221 and a channel layer 202 located between adjacent gate grooves 221. The semiconductor device also includes a gate structure 222, located on the substrate 200 and across the fin. The gate structure 222 covers a sidewall and a top of the fin of the first region 211, filling the gate groove 221 and surrounding the channel layer 202. A width of the gate structure 222 located in the gate groove 221 is smaller than a width of the gate structure 222 located at the top of the fin of the first region 211.

The another semiconductor device also includes a barrier layer 226. A sidewall of the barrier layer 226 is flush with the sidewall of the second sidewall spacer 210.

The embodiments disclosed in the present disclosure are exemplary only and not limiting the scope of the present disclosure. Various combinations, alternations, modifications, or equivalents to the technical solutions of the disclosed embodiments can be obvious to those skilled in the art and can be included in the present disclosure. Without departing from the spirit of the present disclosure, the technical solutions of the present disclosure may be implemented by other embodiments, and such other embodiments are intended to be encompassed within the scope of the present disclosure.

What is claimed is:

1. A semiconductor device, comprising:
a substrate;
a fin, located on the substrate; and
a gate structure, located on the substrate and across the fin,
wherein:
the fin includes a first region, and the fin of the first region includes a gate groove and a channel layer located between adjacent gate grooves;
the gate structure covers a sidewall and a top of the fin of the first region, fills the gate groove and surrounds the channel layer; and
a width of the gate structure located in the gate groove is smaller than a width of the gate structure located on the top of the fin of the first region.

2. The device according to claim 1, further comprising a sidewall spacer, wherein:
the sidewall spacer is located on a sidewall of the gate structure; and
the sidewall spacer includes a stacked structure including a first sidewall spacer and a second sidewall spacer, wherein:
the first sidewall spacer is located on a sidewall of the gate structure; and
the second sidewall spacer is located on a sidewall of the first sidewall spacer.

3. The device according to claim 2, further comprising a barrier layer, wherein:
the barrier layer is located on a sidewall of the gate structure in the gate groove.

4. The device according to claim 3, wherein:
a sidewall of the barrier layer is located between the sidewall of the first sidewall spacer and a sidewall of the second sidewall spacer; or
the sidewall of the barrier layer is located between the sidewall of the gate structure and the sidewall of the first sidewall spacer; or
the sidewall of the barrier layer is flush with the sidewall of the second sidewall spacer.

5. The device according to claim 1, wherein:
the fin further includes a second region and a source/drain doped layer located in the fin of the second region; and
the fin of the second region is located on two sides of the gate structure.

6. The device according to claim 1, wherein:
the channel layer is made of monocrystalline silicon.

7. The device according to claim 2, wherein the gate structure includes:
a gate dielectric layer formed on a surface of the channel layer and a sidewall of the first sidewall spacer;
a work function layer on the gate dielectric layer; and
a gate electrode layer on the work function layer.

8. The device according to claim 7, wherein:
the gate dielectric layer is made of a high-k dielectric material with a dielectric coefficient k greater than approximately 3.9; and
the high-k dielectric material includes at least one or a combination of hafnium oxide, zirconium oxide, hafnium silicon oxide, lanthanum oxide, zirconium silicon oxide, titanium oxide, tantalum oxide, barium strontium titanium oxide, barium titanium oxide, strontium titanium oxide, or aluminum oxide.

9. The device according to claim 7, wherein:
the work function layer is made of a material including at least one or a combination of titanium nitride, aluminum titanium, or tantalum nitride.

10. The device according to claim 5, further comprising a dielectric layer, wherein:
the dielectric layer is located on top of the source/drain doped layer and covers the sidewall of the gate structure.

11. A forming method of a semiconductor device, comprising:
providing a substrate;
forming a fin on the substrate, wherein the fin includes a plurality of sacrificial layers stacking along a normal direction of a surface of the substrate, and a channel layer located between two adjacent sacrificial layers;
forming a dummy gate structure on the substrate and across the fin;
etching the fin on two sides of the dummy gate structure, thereby forming a source/drain groove in the fin; and
etching a portion of the sacrificial layer on a sidewall of the source/drain groove, thereby forming a modified sacrificial layer, wherein a width of the modified sacrificial layer is smaller than a width of the dummy gate structure at a top of the fin.

12. The method according to claim 11, before etching the fin on the two sides of the dummy gate structure, thereby forming the source/drain groove in the fin, further comprising:
forming a sidewall spacer on a sidewall of the dummy gate structure, wherein:
the sidewall spacer includes a stacked structure, including a first sidewall spacer and a second sidewall spacer;
the first sidewall spacer is located on the sidewall of the dummy gate structure; and
the second sidewall spacer is located on a sidewall of the first sidewall spacer.

13. The method according to claim 12, wherein:
in a process of etching the portion of the sacrificial layer on the sidewall of the source/drain groove, thereby forming the modified sacrificial layer, a sacrificial-layer groove is formed on two sides of the modified sacrificial layer, and a barrier layer is formed in the sacrificial-layer groove.

14. The method according to claim 13, wherein:
a sidewall of the barrier layer is located between the sidewall of the first sidewall spacer and a sidewall of the second sidewall spacer; or
the sidewall of the barrier layer is located between the sidewall of the gate structure and the sidewall of the first sidewall spacer; or
the sidewall of the barrier layer is flush with the sidewall of the second sidewall spacer.

15. The method according to claim 13, after forming the barrier layer, further comprising:
forming a source/drain doped layer in the source/drain groove;
forming a dielectric layer on the substrate source/drain doped layer, wherein the dielectric layer covers the sidewall of the dummy gate structure;
removing the dummy gate structure, thus forming a gate opening in the dielectric layer;
removing the modified sacrificial layer, thus forming a gate groove between adjacent channel layers, between the channel layer and the substrate, and on a top of the channel layer; and
forming a gate structure in the gate opening and the gate groove, wherein the gate structure surrounds the channel layer.

16. The method according to claim 11, wherein forming the fin on the substrate includes:
forming a fin material film on the substrate, wherein the fin material film includes a plurality of fin sacrificial material films stacking along the normal direction of the surface of the substrate, and an initial channel material film located between two adjacent fin sacrificial material films;
forming a patterned layer on the fin material film; and
using the patterned layer as a mask to etch the fin material film until the surface of the substrate is exposed, thereby forming the fin.

17. The method according to claim 11, after forming the fin on the substrate and before forming the dummy gate structure on the substrate and across the fin, further comprising:
etching a portion thickness of the substrate using the fin as a mask; and
forming an isolation structure on the substrate, wherein a top surface of the isolation structure is flush with or lower than a top surface of the substrate.

18. The method according to claim 12, wherein the dummy gate structure includes:
a dummy gate dielectric layer on the fin;
a dummy gate layer on the dummy gate dielectric layer; and
a protection layer on the dummy gate layer.

19. The method according to claim 18, wherein forming the sidewall spacer on the sidewall of the dummy gate structure includes:
forming a sidewall spacer material layer on a top surface of the dummy gate dielectric layer, a sidewall of the dummy gate layer, and a sidewall and a top surface of the protection layer; and
etching back the sidewall spacer material layer until the top surface of the protection layer and the top surface of the dummy gate dielectric layer are exposed, thereby forming the sidewall spacer.

20. The method according to claim 13, wherein a process of forming the barrier layer includes:
on a sidewall and a bottom surface of the source/drain groove, on a sidewall of the modified sacrificial layer, and on a sidewall and a top surface of the dummy gate structure, forming a first initial barrier layer;
etching back the first initial barrier layer until the bottom surface of the source/drain groove and the top surface of the dummy gate structure are exposed, thereby forming a second initial barrier layer;
etching back the second initial barrier layer until the sidewall of the channel layer is exposed, thereby forming a third initial barrier layer; and
etching back the third initial barrier layer until a portion of the sacrificial-layer groove is exposed, thereby forming the barrier layer.
